(19) United States
(12) Patent Application Publication
(10) Pub. No.: US 2005/0285254 A1
(43) Pub. Date: Dec. 29, 2005

(54) Semiconducting device having stacked dice

(76) Inventors: Joan Rey V. Buot, Cebu (PH); Mauricio L. Lalikan, Cavite (PH)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(21) Appl. No.: 10/874,521

(22) Filed: Jun. 23, 2004

(51) Int. Cl. H01L 21/30; H01L 21/46; H01L 21/4763; H01L 23/02; H01L 23/053; H01L 23/12

(52) U.S. Cl. 257/700; 438/618

(57) ABSTRACT

Some embodiments of the present invention relate to a semiconducting device that includes a base layer and a first layer mounted on an upper surface of the base layer. The first layer includes an upper surface and an opening such that a first die is attached to the upper surface of the base layer within the opening. A second die is attached to the upper surface of the first layer such that the second die is stacked above the first die. The semiconducting device may further include a second layer on the upper surface of the first layer. The second layer includes an opening and an upper surface such that the second die is within the opening in the second layer. In addition, a third die may be attached to the upper surface of the second layer such that the third die is stacked above the first and second dice.

### TECHNICAL FIELD

Some embodiments of the present invention relate to a semiconducting device, and in particular, to a semiconducting device that includes stacked dice, and to manufacturing methods related thereto.

### BACKGROUND

High performance semiconducting devices are continually being redesigned in order to increase processing speed and/or power. Each increase in processing speed and power generally carries a cost of increased size such that additional innovations must be made in order to minimize the size of the semiconducting devices. Manufacturers of semiconducting devices continually try to improve product performance and reduce product size while minimizing production costs.

Several methods have been employed to improve the speed of semiconducting devices while minimizing the size of semiconducting devices. One method includes stacking multiple dice onto a substrate that electrically connects one or more of the stacked dice to other electronic components which make up part of an electronic system.

The dice in the stack are typically separated by individual spacers. Some of the dice within the stack may include active circuitry that is exposed on the upper surface of the die (e.g., a flash memory array). The active circuitry is usually slightly larger than the spacer such that wires can be bonded to the active circuitry on one or more sides of the spacer.

One drawback with stacking dice in this manner is that the spacer places the exposed active circuitry under stress that varies relative to the position of the active circuitry on the die. The varying stress across the upper surface of the die causes the transconductance (gm) of the die to change at different positions on the die. In semiconducting devices where the active circuitry on the die includes logic circuitry, the gm degradation may result in timing failures due to transistor current changes within the logic circuitry.

Another drawback with stacking dice in this manner is that there are often problems associated with wire-bonding one or more of the stacked dice to the substrate. As an example, wires may be inadvertently swept away from their intended location as the stack of dice is encapsulated. There may also be unwanted short circuiting from the dripping or splattering of conductive material which can occur as wires are bonded to one or more of the dice. In addition, as the number of dice in a stack increases, the drawbacks that are associated with wire-bonding may be exacerbated because many of the wires need to be relatively long in order to reach some of the dice in the stack.

### BRIEF DESCRIPTION OF THE DRAWINGS

FIG. 1 is a schematic section view of an example semiconducting device that includes stacked dice.

FIG. 2 is a perspective view of an example base layer and first layer that may be part of the semiconducting device shown in FIG. 1.

FIG. 3 is a plan view of the base layer and first layer shown in FIG. 2.

FIG. 4 is a schematic section view of the base layer and first layer shown in FIG. 2 taken along line 4-4.

FIG. 5 is a plan view similar to FIG. 3 illustrating another example base layer and first layer that may be part of the semiconducting device shown in FIG. 1.

FIG. 6 is a plan view similar to FIGS. 3 and 5 illustrating another example base layer and first layer that may be part of the semiconducting device shown in FIG. 1.

FIG. 7 is a schematic section view of another example semiconducting device that includes stacked dice.

FIG. 8 is a perspective view of an example base layer, first layer and second layer that may be part of the semiconducting device shown in FIG. 7.

FIG. 9 is a plan view of the base layer, first layer and second layer shown in FIG. 8.

FIG. 10 is a schematic section view of the base layer, first layer and second layer shown in FIG. 8 taken along line 10-10.

FIG. 11 is a plan view similar to FIG. 9 illustrating another example base layer, first layer and second layer that may be part of the semiconducting device shown in FIG. 7.

FIG. 12 is a plan view similar to FIGS. 9 and 11 illustrating another example base layer, first layer and second layer that may be part of the semiconducting device shown in FIG. 7.

FIG. 13 illustrates a method of fabricating a semiconducting device that includes stacked dice.

FIG. 14 is a block diagram of an electronic system that incorporates at least one semiconducting device or method of the type shown in FIGS. 1-13.

### DETAILED DESCRIPTION

In the following detailed description, reference is made to the accompanying drawings. In the drawings, like numerals describe substantially similar components throughout the several views. Other embodiments may be utilized, and structural, logical, and electrical changes may be made.

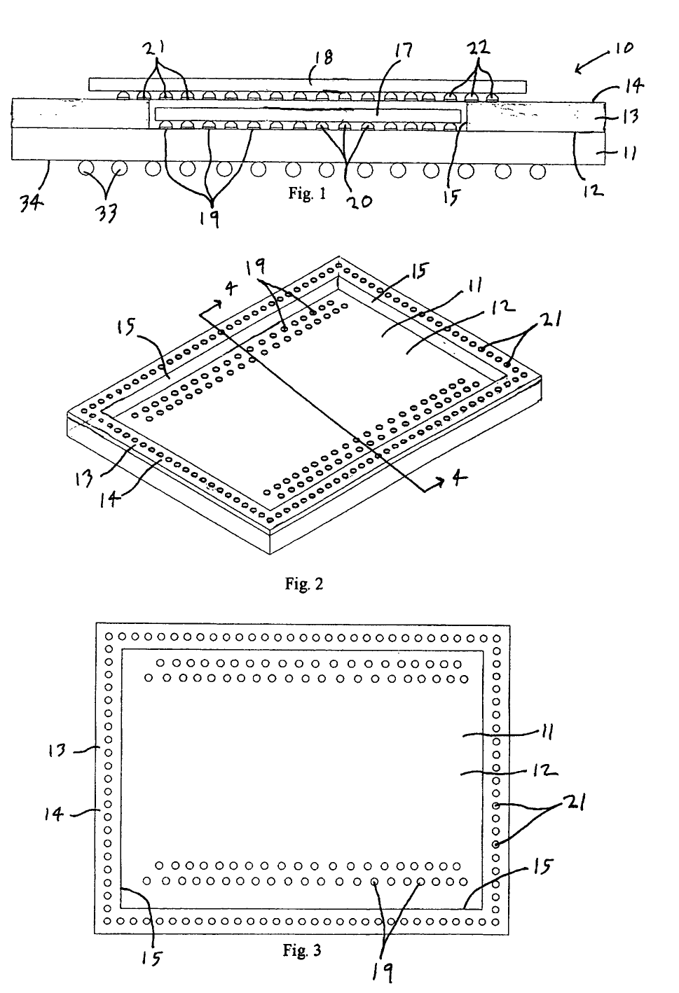

FIG. 1 illustrates a semiconducting device 10 that includes a base layer 111 having an upper surface 12, and a first layer 13 which is mounted on the upper surface 12 of base layer 11. The first layer 13 includes an upper surface 14 and an opening 15.

The semiconducting device 10 further includes a first die 17 that is attached to the upper surface 12 of base layer 11 within the opening 15 in first layer 13. A second die 18 is attached to the upper surface 14 of first layer 13 such that second die 18 is stacked above first die 17.

In the illustrated example embodiment, second die 18 does not mechanically engage first die 17 because first layer 13 is thicker than first die 17. In other embodiments, first and second dice 17, 18 may directly engage one another or be mechanically coupled together by some type of material (e.g., an epoxy).

The first die 17 may be secured to the upper surface 12 of base layer 11 using an adhesive, conductive epoxy or some form of solder attachment (among other methods). In the illustrated example embodiment, first die 17 is surface mounted to base layer 11 using a conventional C4 joint. It should be noted that the C4 joint may be supplemented by an underfill (e.g., an epoxy).

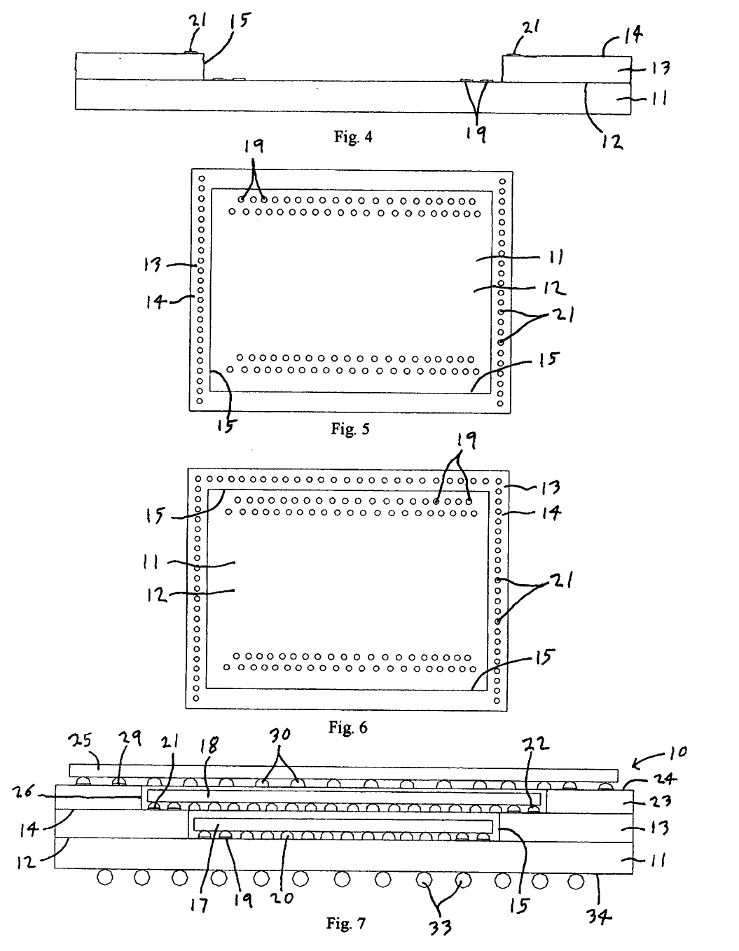

The upper surface 12 of base layer 11 may include one or more contacts (see, e.g., pads 19 in FIGS. 1-4) that are joined to one or more contacts (see, e.g., solder balls 20 in FIG. 1) on first die 17. It should be noted that the number, size, shape, arrangement and/or alignment of the contacts on base layer 11 and first die 17 will depend in part on the application where the semiconducting device 10 is to be used.

The second die 18 may be secured to the upper surface 14 of first layer 13 using an adhesive, conductive epoxy or some form of solder attachment (among other methods). In the illustrated example embodiment, second die 18 is surface mounted to the upper surface 14 of first layer 13 using a conventional C4 joint. In some forms, the C4 joint may be supplemented by an underfill (e.g., an epoxy). As an example, the upper surface 14 of first layer 13 may include one or more contacts (see, e.g., pads 21 in FIGS. 1-4) that are joined to one or more contacts (see, e.g., solder balls 22 in FIG. 1) on second die 18.

FIGS. 2-3 show that the pads 21 on first layer 13 may be positioned on each side of the opening 15 in first layer 13 such that second die 18 (second die 18 shown in FIG. 1) is attached to the upper surface 14 of first layer 13 on each side of the opening 15. FIG. 5 shows an alternative embodiment where the pads 21 on first layer 13 may be positioned on opposing sides of the opening 15 such that second die 18 (second die 18 shown in FIG. 1) is attached to the upper surface 14 of first layer 13 on opposing sides of the opening 15. FIG. 6 shows another alternative embodiment where the pads 21 on first layer 13 may be positioned on three sides of the opening 15 such that second die 18 (second die 18 shown in FIG. 1) is attached to the upper surface 14 of first layer 13 on three sides of the opening 15.

Although the opening 15 is shown as rectangular, it should be noted that opening 15 may be any shape. In some embodiments, the opening 15 may be concentric with first die 17 to reduce the size of semiconducting device 10.

As shown in FIG. 7, semiconducting device 10 may further include a second layer 23 that is on the upper surface 14 of first layer 13, and a third die 25 which is attached to an upper surface 24 of second layer 23. The second layer 23 includes an opening 26 such that second die 18 is within the opening 26 in second layer 23 and third die 25 is stacked above first and second dice 17, 18.

In the illustrated example embodiment, third die 25 does not mechanically engage second die 18 and/or first die 17 because second layer 23 is thicker than second die 18. In other embodiments, third die 25 may directly engage first and second dice 17, 18, or be mechanically coupled to first and second dice 17, 18 by some type of material (e.g., an epoxy).

Third die 25 may be secured to the upper surface 24 of second layer 23 using an adhesive, conductive epoxy or some form of solder attachment (among other methods). In the illustrated example embodiment, third die 25 is surface mounted to second layer 23 using a conventional C4 joint. It should be noted that the C4 joint may be supplemented by an underfill (e.g., an epoxy).

It should be noted that although the opening 26 is shown as rectangular, opening 26 may be any shape. In some embodiments, opening 26 may be concentric with second die 18 to reduce the size of semiconducting device 10. In addition, some of the dice 17, 18, 25 within the stack may include active circuitry (e.g., a flash memory array or logic circuitry) that is exposed on the upper surfaces of the dice 17, 18, 25.

As an example, the upper surface 24 of second layer 23 may include one or more contacts (see, e.g., pads 29 in FIGS. 7-10) that are joined to one or more contacts (see, e.g., solder balls 30 in FIG. 7) on third die 25. It should be noted that the number, size, shape, arrangement and/or alignment of the contacts on second layer 23 and third die 25 will depend in part on the application where the semiconducting device 10 is to be used. As examples, the contacts may be arranged linearly or staggered along the sides of opening 26.

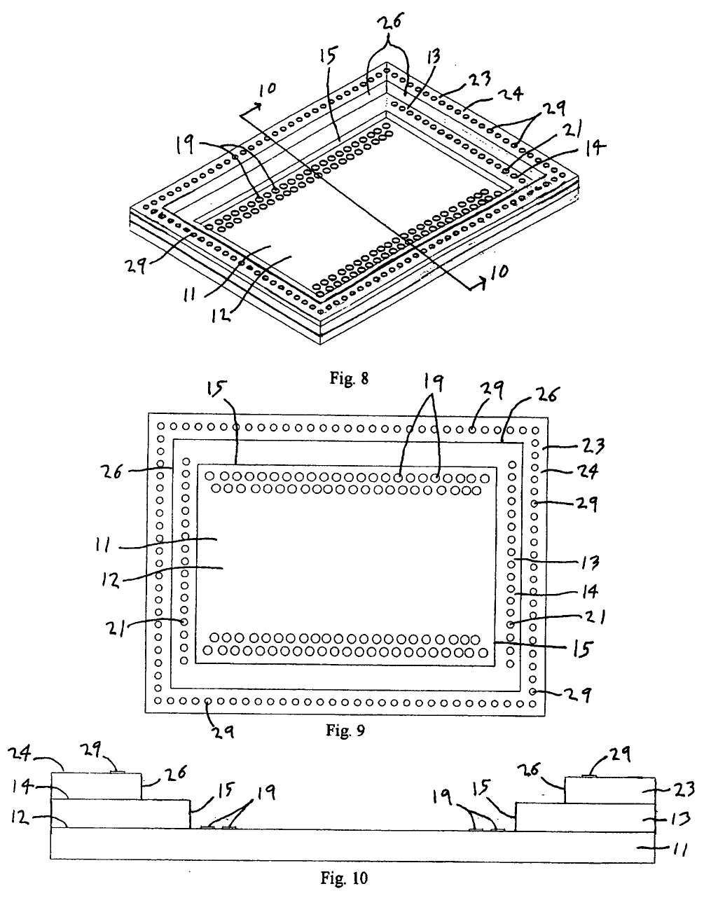

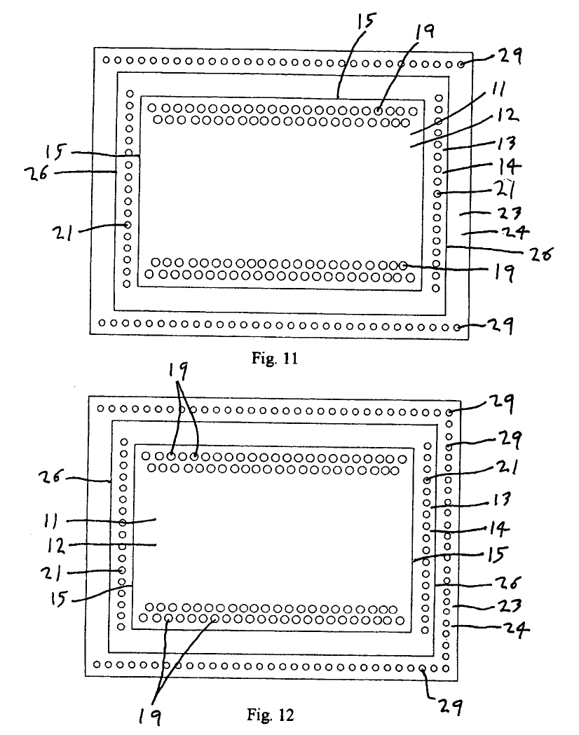

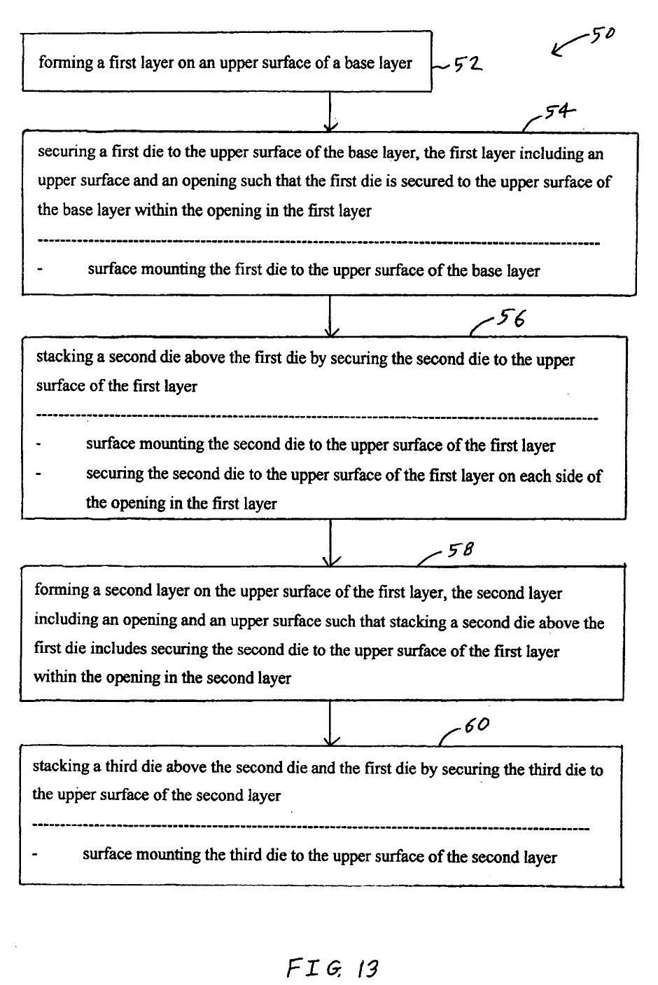

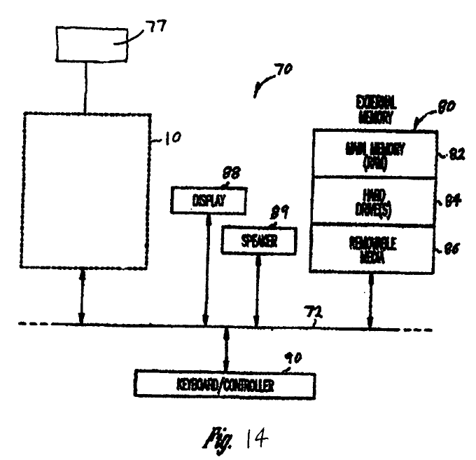

FIGS. 8-9 show that the pads 29 on second layer 23 may be positioned on each side of the opening 26 in second layer 23 such that third die 25 is attached to the upper surface 24 of second layer 23 on each side of the opening 26. FIG. 11 shows an alternative embodiment where the pads 29 on second layer 23 may be positioned on opposing sides of the opening 26 such that third die 25 is attached to the upper surface 24 of second layer 23 on opposing sides of the opening 26. FIG. 12 shows another alternative embodiment where the pads 29 on second layer 23 may be positioned on three sides of the opening 26 such that third die 25 is attached to the upper surface 24 of second layer 23 on three sides of the opening 26.

In the illustrated example embodiment, base layer 11, first layer 13 and second layer 23 are made from the same material, although different materials may be used for each layer. A number of materials may be used for base layer 11, first layer 13 and/or second layer 23. The choice of materials will depend on the relevant circuit design considerations and the costs that are associated with fabricating semiconducting device 10 (among other factors). Some example materials for the layers include Bismaleimide Triazine, Polyimide, Aramid, Flourpolymer, Polyetherimide, polyester, polyethylene, Polyethylene napathalate. polysulfone, polyvinylchloride, Polyvinylflouride or some other dielectric material (among others).

It should be noted that one or more of the layers 11, 13, 23 may include any number of conductive or semiconductive traces, paths and/or vias to facilitate transferring signals between the layers 11, 13, 23 and/or dice 17, 18, 25. In addition, other example embodiments are contemplated where additional layers are added to semiconducting device 10 such that additional dice are placed within openings in the layers to add to the stack of dice.

As shown in FIGS. 1 and 7, first layer 11 may include solder balls 33 (or some other type of contact) on a bottom surface 34 of base layer 11. The solder balls 33 allow the first layer 11 to be attached to a substrate, motherboard or some other electrical component that may be part of an electronic system.

Referring now also to FIG. 13, an example method 50 of fabricating a semiconducting device 10 having stacked dice includes 52 forming a first layer 13 on an upper surface 12 of a base layer 11, and 54 securing a first die 17 to the upper surface 12 of the base layer 11. It should be noted that first layer 13 may be formed on an upper surface 12 of a base layer 11 in any manner.

The first layer 13 includes an upper surface 14 and an opening 15 such that first die 17 is secured to the upper surface 12 of base layer 11 within the opening 15. The method further includes 56 stacking a second die 18 above first die 17 by securing second die 18 to the upper surface 14 of first layer 13.

In some example embodiments, 54 securing first die 17 to the upper surface 12 of base layer 11 may include surface mounting first die 17 to the upper surface 12 of base layer 11, although other methods may be used to secure first die 17 to base layer 11. In addition, 56 stacking second die 18 above first die 17 may include surface mounting second die 18 to the upper surface 14 of first layer 13, although other methods may be used to secure second die 18 to first layer 13. It should also be noted that 56 stacking second die 18 above first die 17 may include securing second die 18 to the upper surface 14 of first layer 13 on (i) each side of the opening 15 in first layer 13; (ii) three sides of the opening 15 in first layer 13; or (iii) opposing sides of the opening 15 in first layer 13.

The method 50 may further include 58 forming a second layer 23 on the upper surface 14 of first layer 13. Second layer 23 may include an opening 26 and an upper surface 24 such that stacking second die 18 above first die 17 includes securing second die 18 to the upper surface 14 of first layer 13 within the opening 26 in second layer 23.

The method 50 may further include 60 stacking a third die 25 above second die 18 by securing third die 25 to the upper surface 24 of second layer 23. In some example embodiments, 60 stacking a third die 25 above second die 18 may include surface mounting third die 25 to the upper surface 24 of second layer 23, although other methods may be used to secure third die 25 to second layer 23.

Although three layers 11, 13, 23 and three dice 17, 18, 25 are shown in FIG. 7, any number of layers and/or dice may be added as part of the embodiments of methods according to the present invention described herein. In addition, the example processes that are described with reference to FIG. 13 need not be performed in any particular order.

FIG. 14 is a block diagram of an electronic system 70, such as a computer system, that includes a semiconducting device 10 which is electrically coupled to various components in electronic system 70 via a system bus 72. Any of the semiconducting devices 10 described or referenced herein may be electrically coupled to system bus 72.

Semiconducting device 10 may include a microprocessor, a microcontroller, a graphics processor or a digital signal processor, memory, flash memory and/or a custom circuit or an application-specific integrated circuit, such as a communications circuit for use in wireless devices such as cellular telephones, pagers, portable computers, two-way radios, and similar electronic systems. System bus 72 may be a single bus or any combination of busses.

The electronic system 70 may also include an external memory 80 that in turn includes one or more memory elements suitable to the particular application, such as a main memory 82 in the form of random access memory (RAM), one or more hard drives 84, and/or one or more drives that handle removable media 86, such as floppy diskettes, compact disks (CDs) and digital video disks (DVDs).

The electronic system 70 may also include a display device 88, a speaker 89, and a controller 90, such as a keyboard, mouse, trackball, game controller, microphone, voice-recognition device, or any other device that inputs information into the electronic system 70.

In some embodiments, electronic system 70 may further include a voltage source 77 that is electrically coupled to semiconducting device 10. Voltage source 77 may be used to supply power to one or more of the dice that are stacked within semiconducting device 10.

Semiconducting device 10 can be implemented in a number of different embodiments. The elements, materials, geometries, dimensions, and sequence of operations can all be varied to suit particular packaging requirements. Parts of some embodiments may be included in, or substituted for, those of other embodiments. As an example, any of the semiconducting devices 10 described herein may be incorporated into any of items referenced in FIG. 14.

FIGS. 1-14 are merely representational and are not drawn to scale. Certain proportions thereof may be exaggerated while others may be minimized. Many other embodiments will be apparent to those of skill in the art.

1-24. (canceled)

25. A semiconducting device comprising:
a base layer having an upper surface and a lower surface;
a first layer that engages the upper surface of the base layer, the first layer including an upper surface and an opening;
a first die engaging the upper surface of the base layer within the opening in the first layer; and
a second die engaging the upper surface of the first layer such that the second die is stacked above the first die with open space between the first die and the second die.

26. The semiconducting device of claim 25, wherein the base layer and first layer are substantially the same thickness.

27. The semiconducting device of claim 25, wherein the second die engages the upper surface of the first layer on each side of the opening in the first layer.

28. The semiconducting device of claim 25, wherein the first die is surface mounted to the upper surface of the base layer and the second die is surface mounted to the upper surface of the first layer.

29. The semiconducting device of claim 25, further comprising:
a second layer that engages the upper surface of the first layer, the second layer including an upper surface and an opening such that the second die is within the opening in the second layer; and
a third die that engages the upper surface of the second layer such that the third die is stacked above the second die and the first die with open space between the third die and the second die.

30. The semiconducting device of claim 29, wherein the base layer, the first layer and the second layer are substantially the same thickness.

31. The semiconducting device of claim 29, wherein the third die is attached to the upper surface of the second layer on each side of the opening in the second layer.

32. The semiconducting device of claim 29, wherein the third die is surface mounted to the upper surface of the second layer.

33. The semiconducting device of claim 29, wherein the second layer, the first layer and the base layer are made from the same material.

34. The semiconducting device of claim 29, further comprising solder balls on the lower surface of the base layer.

35. A method comprising:
forming a first layer on an upper surface of a base layer such that the first layer engages the upper surface of the base layer;
securing a first die to the upper surface of the base layer such that the first die engages the upper surface of the base layer, the first layer including an upper surface and an opening such that the first die is within the opening in the first layer; and
stacking a second die above the first die by securing the second die directly to the upper surface of the first layer such that there is open space between the first die and the second die.

36. The method of claim 35, further comprising forming a second layer on the upper surface of the first layer such that the second layer engages the upper surface of the first layer, the second layer including an opening and an upper surface such that stacking a second die above the first die includes engaging the second die with the upper surface of the first layer within the opening in the second layer.

37. The method of claim 36, further comprising stacking a third die above the second die and the first die by securing the third die directly to the upper surface of the second layer such that there is open space between the third die and the second die.

38. The method of claim 37, wherein stacking the third die above the second die and the first die includes surface mounting the third die to the upper surface of the second layer, and stacking the second die above the first die includes surface mounting the second die to the upper surface of the first layer, and securing the first die to the upper surface of the base layer includes surface mounting the first die to the upper surface of the base layer.

39. The method of claim 35, wherein stacking the second die above the first die includes engaging the second die with the upper surface of the first layer on each side of the opening in the first layer.

40. An electronic system comprising:
a bus;
a memory coupled to the bus; and
a semiconducting device coupled to the bus, the semiconducting device including a base layer having an upper surface and a first layer that engages the upper surface of the base layer, the first layer including an upper surface and an opening such that a first die engages the upper surface of the base layer within the opening in the first layer and a second die engages the upper surface of the first layer to stack the second die above the first die, the semiconducting device further including a second layer that engages the upper surface of the first layer, the second layer including an opening and an upper surface such that the second die is within the opening in the second layer, and wherein the semiconducting device further includes a third die that engages the upper surface of the second layer such that the third die is stacked above the second die and the first die.

41. The electronic system of claim 40, further comprising a voltage source coupled to the semiconducting device.

42. The electronic system of claim 40, wherein the second die engages the upper surface of the first layer such that there is open space between the second die and the first die and the third die engages the upper surface of the second layer such that there is open space between the third die and the second die.

43. The electronic system of claim 40, wherein the base layer, the first layer and the second layer are substantially the same thickness.
